(19) United States
(12) Patent Application Publication
(10) Pub. No.: US 2008/0251280 A1
(43) Pub. Date: Oct. 16, 2008

(54) SOLDERING STRUCTURE BETWEEN CIRCUIT BOARDS

(75) Inventors: Honmo SHI, Sakura-shi (JP); Hiroki Maruo, Sakura-shi (JP)

Correspondence Address: SUGHRUE MION, PLLC, 2100 PENNSYLVANIA AVENUE, N.W., SUITE 800, WASHINGTON, DC, 20037, US

(73) Assignee: Fujikura Ltd., Tokyo (JP)

(21) Appl. No.: 11/850,189

(22) Filed: Sep. 5, 2007

(30) Foreign Application Priority Data
Sep. 12, 2006 (JP) P2006-246974

(51) Int. Cl. H05K 1/14; B29C 65/02

(52) U.S. Cl. 174/254; 156/60

(57) ABSTRACT

A substrate coupling structure including a flexible circuit board having first conductors provided thereon, a rigid circuit board having second conductors provided thereon so as to face the first conductors, solder plating disposed on at least one of the first conductors and the second conductors, and an insulating layer which has a thickness larger than the sum of thicknesses of the first and second conductors while having a thickness smaller than the sum of the thicknesses of the first and second conductors plus a thickness of the solder plating.

### CROSS REFERENCE TO RELATED APPLICATIONS

This application claims priority from the Japanese Patent Application No. P2006-246974, filed on Sep. 12, 2006; the entire contents of which are incorporated herein by reference.

### BACKGROUND OF THE INVENTION

1. Field of the Invention

The present invention relates to a technology of coupling printed circuit boards, and more particularly relates to a substrate coupling structure for connecting a plurality of terminals in a rigid circuit board and a flexible circuit board.

2. Description of the Related Art

As a method for electrically coupling printed circuit boards such as a rigid circuit board and a flexible circuit board, there is a method for soldering conductors to each other on a pair of printed circuit boards. To be more specific, solder plating is provided on a surface of at least one of the conductors on the pair of printed circuit boards, and a flux that facilitates soldering is further applied thereto. Thereafter, the conductors on both the printed circuit boards are superimposed on each other. Accordingly, the printed circuit boards are coupled to each other by applying pressure thereon while heating the boards at a predetermined temperature.

The recent advancement in miniaturized and fine-pitched wiring patterns on a printed circuit board makes short-circuiting more likely to occur between conductor patterns to be connected due to formation of solder bridges.

Consequently, as a substrate coupling method for preventing short-circuiting between the conductor patterns to be connected, the following coupling method has been disclosed (see, for example, Japanese Patent Applications No. P2004-342969). Specifically, a substrate coupling structure includes: a circuit board on which first connection lands as a plurality of conductor patterns are formed; and a flexible circuit board which is disposed so as to face the circuit board and includes second connection lands disposed so as to face the first connection lands on the circuit board and insulating layers formed so as to at least partially surround peripheral portions of the second connection lands. In the structure, the first and second connection lands are bonded by use of bonding members, and the insulating layers are formed to have a thickness larger than the sum of thicknesses of the first and second connection lands. In such a substrate coupling structure, even if the connection lands are miniaturized, short-circuiting is never caused by flow of the bonding members such as solder.

However, in soldering, poor adhesion between the connection lands and the solder makes it difficult for heat from a heater chip to be transmitted due to poor heat conduction. Accordingly, good metal-to-metal bonding cannot be obtained since the solder is not melted or not sufficiently melted. Thus, bond strength may become insufficient. As to the substrate coupling structure disclosed in Japanese Patent Applications No. P2004-342969, description is given only of the point that the thickness of the insulating layer is larger than the sum of thicknesses of conductor layers on circuit boards to be coupled. In this structure, no heat is transmitted to the connection lands from the heater chip. Thus, peel-off and the like are likely to occur due to insufficient bond strength between the conductor patterns.

### SUMMARY OF THE INVENTION

According to an aspect of the present invention there is provided a substrate coupling structure including a flexible circuit board having first conductors provided thereon, a rigid circuit board having second conductors provided thereon so as to face the first conductors, solder platings disposed on at least one of the first conductors and the second conductors, and insulating layers which are provided between the first conductors and between the second conductors and each of which has a thickness larger than the sum of thicknesses of the first and second conductors while having a thickness smaller than the sum of the thicknesses of the first and second conductors plus a thickness of the solder platings.

### BRIEF DESCRIPTION OF THE DRAWINGS

FIG. 1 is a first schematic cross-sectional view of a substrate coupling structure according to a first non-limiting exemplary embodiment of the present invention.

FIG. 2 is a second schematic cross-sectional view of the substrate coupling structure according to the first non-limiting exemplary embodiment of the present invention.

FIG. 3 is a third schematic cross-sectional view of the substrate coupling structure according to the first non-limiting exemplary embodiment of the present invention.

FIG. 4 is a first schematic cross-sectional view of a substrate coupling structure according to a second non-limiting exemplary embodiment of the present invention.

FIG. 5 is a second schematic cross-sectional view of the substrate coupling structure according to the second non-limiting exemplary embodiment of the present invention.

FIG. 6 is a third schematic cross-sectional view of the substrate coupling structure according to the second non-limiting exemplary embodiment of the present invention.

### DETAILED DESCRIPTION OF THE INVENTION

Non-limiting exemplary embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set fourth such as specific signal values, etc. to provide a thorough understanding of the present invention. However, it will be obvious to those skilled in the art that the present invention may be practiced without such specific details.

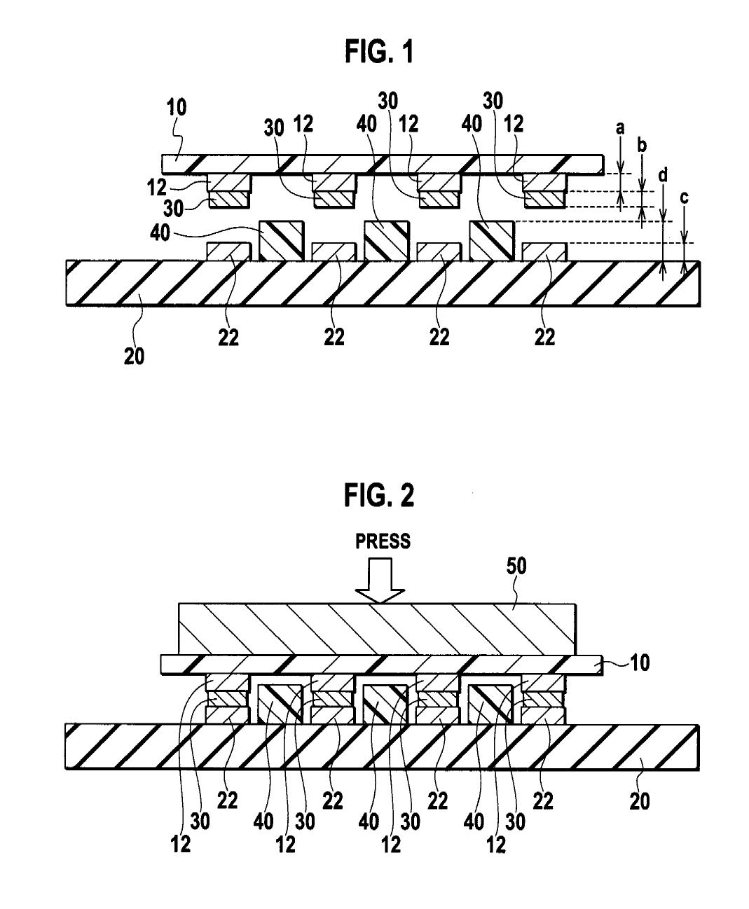

As shown in FIG. 1, a substrate coupling structure according to a first non-limiting exemplary embodiment of the present invention includes: a flexible circuit board 10 having first conductors 12 provided thereon; a rigid circuit board 20 having second conductors 22 provided thereon so as to face the first conductors 12; solder platings 30 disposed on at least one of the first conductors 12 and the second conductors 22; and insulating layers 40 which are provided between the first conductors 12 and between the second conductors 22 and each of which has a thickness larger than the sum of thicknesses of the first and second conductors 12 and 22 while having a thickness smaller than the sum of the thicknesses of the first and second conductors 12 and 22 plus a thickness of the solder platings 30.

The flexible circuit board 10 has flexibility, such as a polyimide circuit board, a polyethylene terephthalate (PET) circuit board and a polyethylene naphthalate (PEN) circuit board, for example. As a thickness of the flexible circuit board 10, thicknesses of 25 μm, 12.5 μm, 8 μm, 6 μm and the like can be adopted.

The rigid circuit board 20 is a rigid circuit board such as a glass epoxy circuit board, a glass composite circuit board and a paper epoxy circuit board, for example. As a thickness of the rigid circuit board 20, thicknesses of 2.4 mm, 2.0 mm, 1.6 mm, 1.2 mm, 1.0 mm, 0.8 mm, 0.6 mm, 0.4 mm and the like can be adopted.

The first conductors 12 are conductor patterns designed on a surface of the flexible circuit board 10. Similarly, the second conductors 22 are conductor patterns designed on a surface of the rigid circuit board 20. The first and second conductors 12 and 22 are formed by patterning a rolled copper foil, an electrolytic copper foil or the like on the flexible circuit board 10 and the rigid circuit board 20. As the first and second conductors 12 and 22, metal foils other than the copper foils can also be used. A pitch width of the first and second conductors 12 and 22 is set to 10 to 500 μm, and a pattern width thereof is set to 10 to 500 μm. As the thickness of the first conductors 12, thicknesses of 35 μm, 18 μm, 12 μm, 9 μm and the like can be adopted. The smaller the thickness of the first conductors 12, the more readily they are to be fine-pitched and flexible. As the thickness of the second conductors 22, a thickness of 35 μm is generally adopted.

On the first and second conductors 12 and 22, cover lay films or the like are disposed as cover layers (not shown). Specifically, the cover lay film includes, as a base material, an insulating polyimide film or the like having good flexibility even after bonding. The cover layer generally has a thickness of 25 μm. An adhesive used to attach the cover layers to each other generally has a thickness of 10 to 30 μm. This means that the sum of the thicknesses of the cover layer and the adhesive is greater than the thicknesses of the first and second conductors 12 and 22. Moreover, exposed portions of the first and second conductors 12 and 22, which are not protected by the cover layers, are subjected to surface treatment such as pre-flux processing, hot air leveling (HAL), electrolytic solder plating and electroless solder plating.

As the solder plating 30, a lead-contained solder paste, a lead-free solder paste, a solder plating, a tin plating and the like can be used.

The insulating layer 40 can be formed by use of a printing method, a drawing method, a photolithography method and the like. As the insulating layer 40, epoxy resin, acrylic resin and the like can be used.

With reference to FIG. 1, definition of the thickness of the insulating layer 40 will be described. As shown in FIG. 1, it is assumed that the thickness of the first conductor 12 is a, the thickness of the solder plating is b, the thickness of the second conductor 22 is c, and the thickness of the insulating layer 40 is d. In this event, the thickness d of the insulating layer 40 is set so as to satisfy the following expressions (1) and (2).

d<a+b+c (1)

d>a+c (2)

When the thickness d of the insulating layer 40 satisfies the expression (1), as shown in FIG. 2, adhesion between the first conductors 12 and the solder platings 30 as well as between the solder platings 30 and the second conductors 22 is realized by pressure application using a heater such as a heater chip 50 while making the first and second conductors 12 and 22 face each other. Thus, heat can be evenly transmitted to a connection part from the heater chip 50.

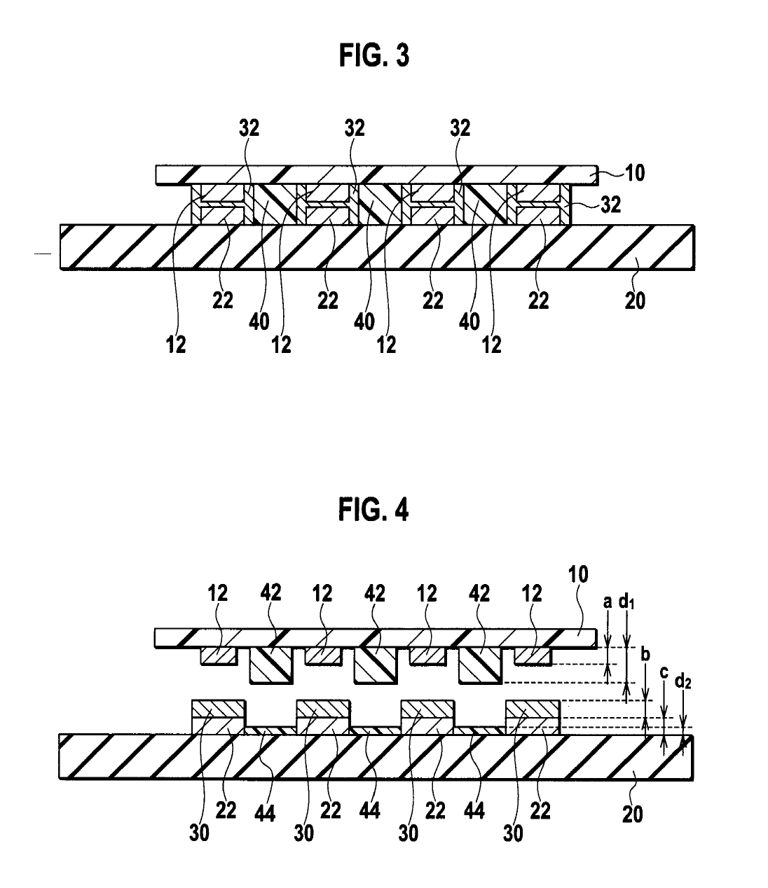

When the thickness d of the insulating layer 40 satisfies the expression (2), as shown in FIG. 3, a gap between the flexible circuit board 10 and the rigid circuit board 20 is secured by the insulating layers 40 even when the solder platings 30 are heated by the heater chip 50 and melted. Therefore, when connection layers 32 are formed by melting the solder platings 30, solder reservoirs are formed in the gap between the flexible circuit board 10 and the rigid circuit board 20. Furthermore, contact of the insulating layers 40 with the flexible circuit board 10 and the rigid circuit board 20 prevents short-circuiting of the connection layers 32 due to flow of the solder.

In the substrate coupling structure according to the first non-limiting exemplary embodiment of the present invention, the heat from the heater chip 50 can be evenly transmitted to the connection part by the insulating layers 40. Thus, it is possible to prevent occurrence of peel-off and the like due to insufficient bond strength between the conductor patterns. Furthermore, formation of the solder reservoirs by the insulating layers 40 enables prevention of short-circuiting between the conductor patterns due to excess solder.

Moreover, in the substrate coupling structure according to the first non-limiting exemplary embodiment, when the flexible circuit board 10 and the rigid circuit board 20 are coupled to each other, positioning of the first and second conductors 12 and 22, which are connected to each other by fitting convexes into concaves, can be easily performed by providing the insulating layers 40.

A substrate coupling structure according to a second non-limiting exemplary embodiment of the present invention is different from that of the first non-limiting exemplary embodiment in a point that insulating layers 42 and 44 are provided separately on a flexible circuit board 10 and a rigid circuit board 20, respectively. Besides the above point, the structure of this non-limiting exemplary embodiment is substantially the same as the connection reinforcement structure shown in FIG. 1. Thus, redundant description will be omitted.

With reference to FIG. 4, definition of thicknesses of the insulating layers 42 and 44 will be described. As shown in FIG. 4, it is assumed that the thickness of the first conductor 12 is a, the thickness of the solder plating is b, the thickness of the second conductor 22 is c, the thickness of the insulating layer 42 is d₁ and the thickness of the insulating layer 44 is d₂. In this event, the thicknesses d₁ and d₂ of the insulating layers 42 and 44 are set so as to satisfy the following expressions (3) and (4).

d₁+d₂<a+b+c (3)

d₁+d₂>a+c (4)

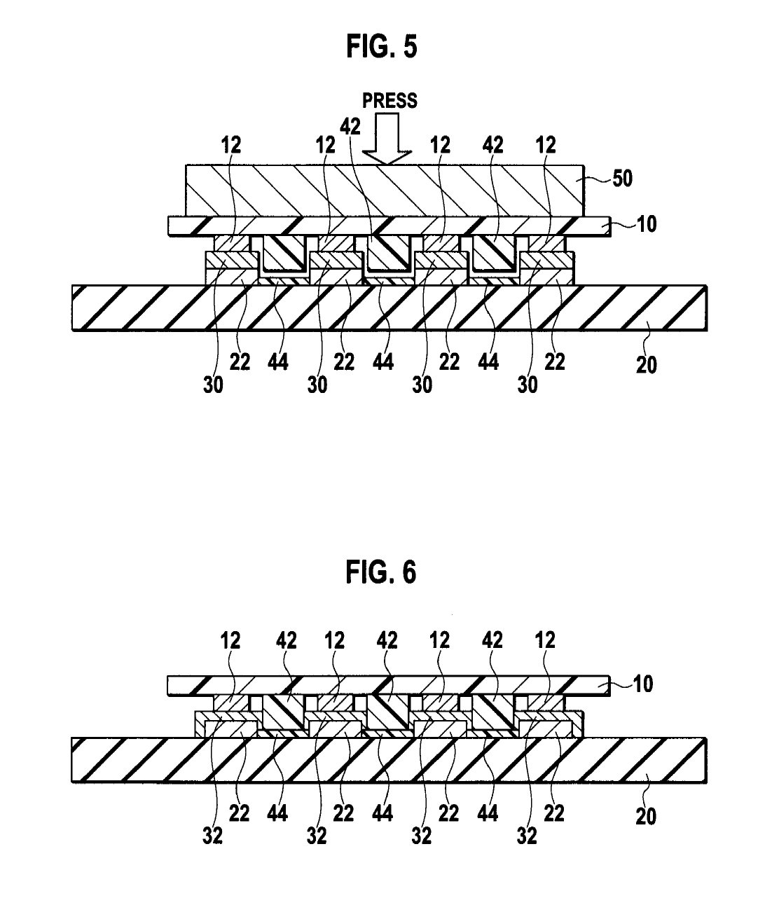

When the thicknesses d₁ and d₂ of the insulating layers 42 and 44 satisfy the expression (3), as shown in FIG. 5, adhesion between the first conductors 12 and the solder platings 30 as well as between the solder platings 30 and the second conductors 22 is realized by pressure application using a heater such as a heater chip 50 while making the first and second conductors 12 and 22 face each other. Thus, heat can be evenly transmitted to a connection part from the heater chip 50.

When the thicknesses d₁ and d₂ of the insulating layers 42 and 44 satisfy the expression (4), as shown in FIG. 6, a gap between the flexible circuit board 10 and the rigid circuit board 20 is secured by the insulating layers 42 and 44 even when the solder platings 30 are heated by the heater chip 50 and melted. Therefore, when connection layers 32 are formed by melting the solder platings 30, solder reservoirs are formed in the gap between the flexible circuit board 10 and the rigid circuit board 20. Furthermore, contact of the insulating layers 42 and 44 with the flexible circuit board 10 and the rigid circuit board 20 prevents short-circuiting of the connection layers 32 due to flow of the solder.

In the substrate coupling structure according to the second non-limiting exemplary embodiment of the present invention, the heat from the heater chip 50 can be evenly transmitted to the connection part by the insulating layers 42 and 44. Thus, it is possible to prevent occurrence of peel-off and the like due to insufficient bond strength between the conductor patterns. Furthermore, formation of the solder reservoirs by the insulating layers 42 and 44 enables prevention of short-circuiting between the conductor patterns due to excess solder.

Moreover, in the substrate coupling structure according to the second non-limiting exemplary embodiment, when the flexible circuit board 10 and the rigid circuit board 20 are coupled to each other, positioning of the first and second conductors 12 and 22, which are connected to each other by fitting convexes into concaves so as to allow the insulating layers 42 and 44 to face each other, can be easily performed by providing the insulating layers 42 and 44.

Furthermore, when the expressions (3) and (4) cannot be satisfied within a range of material selection only by the insulating layers 44 provided on the rigid circuit board 20, the expressions (3) and (4) can sometimes be satisfied by superimposing the insulating layers 44 on the insulating layers 42 provided on the flexible circuit board 10.

The present invention has been described above according to the non-limiting exemplary embodiments. However, it should be understood that the present invention is not limited to the description and drawings which constitute a part of this disclosure. From this disclosure, various alternative embodiments, examples and operational technologies will become apparent to those skilled in the art.

For example, as to the substrate coupling structure according to the non-limiting exemplary first embodiment, the description was given of the case where the insulating layers 40 are provided on the rigid circuit board 20. However, the insulating layers 40 may be provided on the flexible circuit board 10. To be more specific, when the thickness of the first conductors 12 provided on the flexible circuit board 10 is 18 μm, the expressions (1) and (2) are easily satisfied by providing the insulating layers 40 having the thickness of 25 μm as the cover layers.

Various modifications will become possible for those skilled in the art after receiving the teachings of the present disclosure without departing from the scope thereof.

What is claimed is:

1. A substrate coupling structure comprising:
a flexible circuit board having first conductors provided thereon;
a rigid circuit board having second conductors provided thereon so as to face the first conductors;
solder plating disposed on at least one of the first conductors and the second conductors; and
at least one insulating layer provided between the first conductors and between the second conductors the at least one insulating layer has a thickness larger than the sum of thicknesses of the first and second conductors while having a thickness smaller than the sum of the thicknesses of the first and second conductors plus a thickness of the solder plating.

2. The substrate coupling structure of claim 1, wherein the at least one insulating layer is provided on the rigid circuit board.

3. The substrate coupling structure of claim 1, wherein the at least one insulating layer comprises at least two insulating layers separately provided on the flexible circuit board and the rigid circuit board.

4. The substrate coupling structure of claim 1, wherein the at least one insulating layer is provided on the flexible circuit board.

5. A substrate coupling method comprising:
providing a flexible circuit board having first conductors thereon;
providing a rigid circuit board having second conductors thereon so as to face the first conductors;
disposing solder plating on at least one of the first and the second conductors; and
providing at least one insulating layer between at least one conductors of the first conductors and conductors of the second conductors, the at least one insulating layer has a thickness larger than the sum of thicknesses of the first and second conductors while having a thickness smaller than the sum of the thicknesses of the first and second conductors plus a thickness of the solder plating.

6. The substrate coupling method of claim 5, wherein the at least one insulating layer is provided on the rigid circuit board

7. The substrate coupling method of claim 5, wherein the at least one insulating layer comprises at least two insulating layer is separately provided on the flexible circuit board and the rigid circuit board.

8. The substrate coupling method of claim 5, wherein the at least one insulating layer is provided on the flexible circuit board.

9. The substrate coupling method of claim 5 further comprises heating the solder plating to form a connection layer in a gap between the flexible circuit board and the rigid circuit board.
